(19) United States
(12) Patent Application Publication
(10) Pub. No.: US 2022/0308113 A1
(43) Pub. Date: Sep. 29, 2022

(54) METHOD AND SYSTEM FOR CALCULATING THE ENERGY AVAILABLE IN AN ELECTRIC BATTERY AT ANY MOMENT DURING THE LIFE THEREOF, WITHOUT DISCHARGING SAME, AND THE AUTONOMY, CAPACITY AND REMAINING LIFE THEREOF

(71) Applicant: Luis Arturo PARRES GARCÍA, Midrid (ES)

(72) Inventor: Luis Arturo PARRES GARCÍA, Midrid (ES)

(21) Appl. No.: 17/615,277

(22) PCT Filed: Dec. 15, 2020
(86) PCT No.: PCT/ES2020/000058

§ 371 Date: Nov. 30, 2021

(30) Foreign Application Priority Data
Dec. 18, 2019 (ES) P 201900184

(51) Int. Cl. G01R 31/367; H02J 7/00; G01R 31/388

(52) U.S. Cl. CPC G01R 31/367; H02J 7/0048; G01R 31/388

(57) ABSTRACT

This method calculates the available energy, ED, of any battery W, without discharging it, at any temperature Tₙ and at all times. A family of G_{n,l} curves generated, typical of each battery and temperature, discharging batteries of different capacities at a fixed discharge intensity, ID. Discharging W with the same ID produces a response. voltage with which entering G_{n,l}, ED is obtained. It also provides your capacity, autonomy, and remaining life. When the battery is fully charged, ED is the capacity. Calculating L_{w}, the remaining life is found. With the ED and the Balance of Consumption, autonomy is obtained. The above is automated by connecting to a System that comprise: MCU, temperature sensor, discharger, voltmeter, ammeter, interface, etc., obtaining the ED, capacity, autonomy, and remaining life, The use of this method allows the optimization of the batteries, as well as knowing their autonomy, for example, in an EV.

### DESCRIPTION

### The Technical Field

This patent belongs to the electrical sector, to sum up more to the electrochemical one, and specifically to the battery field, both rechargeable and single-use. Until today, there is no reliable way of finding the Available Energy of a battery, from now on ED, without having to discharge it, except for the capacity provided by the manufacturer when new, charged, and at the standardised temperature. This method calculates it at all times in its life; that is to say, when it has aged, it has made unknown partial discharges since its last charge, and all this at any temperature.

### The State of the Art

There are many devices that use electric batteries for autonomous operation. The unpredictable exhaustion of the battery can produce from discomfort to serious problems depending on the circumstances of the equipment that has it in use.

The current problem is the difficulty of knowing the ED of a battery when it is old, without discharging it. It is of great interest that it is not discharged, especially when the energy that the battery still accumulates is needed immediately. It is also important to know how the temperature at which the battery is or will be discharged, affects its autonomy.

The state of the ED a battery is affected by multiple circumstances: such as old age, previous cycling, electrochemical stress suffered, partial discharges since the last recharge and the temperatures at which they have been carried out, including that of the battery at the time of analysis, etc.

In general, everyone has the experience of mobile phone autonomy, and its accelerated loss at the end of its useful life. When the battery is new and freshly charged, the display facilitates the charge status by showing 100% and often a small green battery full in one corner. But when it is old also and freshly charged, the same information also appears, and the autonomy is much lower.

As of today the autonomy of a battery at any time in its life is not known a priori. And especially if the battery is going to be affected by an extreme temperature. This happens because the only information available comes from measuring the voltage, which is not reliable for knowing the ED, the capacity, or the autonomy. The voltage can sometimes give an indication of the state of charge, which is of little value if the capacity is not known.

It is seldom the case that information on the minutes still available on a mobile phone important, although this is not always the case. In general, its charging and usage temperature change little, which helps improve predictability. it helps to link the history of use, previous autonomies, expected capacity loss curve, etc. In other words, extrapolate the history, but you will completely miss the forecast if you then use it in a ski resort.

There are other applications where the lack of knowledge of autonomy can be of enormous relevance. A good example is the electric vehicle EV, where an error in such information can mean not being able to reach a recharging point by your own means. Or in the case of such a point being occupied or damage, knowing whether or not the next point can be reached. In the same way it is important to know the real capacity of the batteries in activities where it is also essential to have certainty of service, such as nuclear power stations, high speed trains, aeroplanes, solar installations, etc.

The following example may be illustrative. In February 2019, Chicago recorded temperatures of −30° C. This is usually about 50° C. difference between the charging and operating temperature of an EV. The capacity loss with such a difference is of the order of 55% of the remaining capacity. This meant that many vehicles that were fully charged and had made a certain journey in the previous days were unable to do so, and were left standing on many roads without power. This is the importance of knowing how temperature affects.

In many cases, this lack of knowledge means that the batteries are now being replaced prematurely because of doubts about the real remaining capacity. Correct information on such a parameter means great savings, since the battery can work to the limit of its life, without making any changes

Once the ED is known, and as an application, we will be able to calculate the autonomy that the equipment has, whether it is a mobile phone, EV, UPS, etc., which is a function of the consumption that is foreseen from that moment. These needs will be detailed in an Electric Balance of Consumption, from now on BEC. It is not the object of this patent to analyse the previous Balance Sheet nor its obtaining, which is considered to be known.

At present, there is no known process or device that provides a satisfactory response to the above problem. In other words, there is nothing that can provide a reliable solution without discharging the battery, which is a basic condition if the available charge is then needed.

Recently, electricity consumption metering devices are coming out that improve information. Some count and memorize the last consumption and then extrapolate. even accompanied by an algorithm that follows the discharge curve. But they do not take into account aspects that drastically influence battery capacity, such as temperature. Please note that charging and usage temperatures can differ greatly. However, we will explain everything we know about this.

There are different methods for calculating the state of charge, including the state of health or conservation, that is the operating situation of the battery. But they only give approximations to the problem we are posing, with great errors and without reliability. Some methods even consist of calculating average values by applying two or more of them in order to try to minimise errors. This is only of statistical interest.

As we have justified, those methods which are based on a total discharge of the battery by applying an energy meter, and which leave the battery unable to be used immediately, are completely discarded. They cannot be applied to primary batteries, nor, of course, to those that are going to change temperature. Without being exhaustive, some of the works consulted are set out below:
a) Those that measure the density of the electrolyte. The main disadvantage of the method is that most batteries are sealed, especially the primary ones, making their use impossible. In accessible batteries, the electrolyte is acid, making the method very unsuitable for the ordinary user because of its danger. It involves the measurement of all the cells that make up the battery, which in installations that have a high voltage, and therefore number of cells, means a considerable amount of time. Even so, the method is far from reliable. In any case, they are unable to make a prediction if the temperature changes. And in no case of the capacity, although they can give an idea of the state of charge, which serves for very little without knowing its capacity.
b) Peukert's Law. It is a classic method. It does not consider the temperature. This simple detail disqualifies it. It can be found explained in many places, one of the simplest is
   https://en.wikipedia.org/wiki/Peukert%27s_law
c) Shepherd's Law. The same commentary can be made. As they are classics very well known, so we do not give more details.
d) Methods based on internal resistance. Apart from the difficulty of data collection, they also do not consider temperature.
   https://www.scienceabc.com/innovation/what-are-the-different-methods-to-estimate-the-state-of-charge-of-batteries.html
e) Some recent works (less than a year and a half old) can be found on the Internet where the basic methods are explained such as:
   https://academicae.unavarra.es/bitstream/handle/2454/21830/TFG_GuembeZab aleta.pdf?sequence=1&isAllowed=y)
f) There are also numerous US patents on the subject. We refer to those we understand that add more consistent aspects to our objective, but without reaching it. The next one we mention, published five months ago, collects all the updated knowledge and, in turn, refers to numerous previous patents. However, it does not consider temperature changes. We will partly rely on it. in this first link it appears as published in the USA Bulletin.
   U.S. Pat. No. 10,30279, dated 28 May 2019. Shoa Hassani Lashidani et al. https://pdfpiw.uspto.gov/.piw?PageNum=0&docid=10302709&IDKey=526056D4F 684&HomeUrl=http%3A%2F%2Fpatft.usptogov%2Fnetacgi%2Fnph-Parser%3FSect1%3DPTO2%2526Sect2%3DHITOFF%2526p%3D1%2526u%3D %25252Fnetahtml%25252FPTO%25252Fsearch-bool.html%2526r%3D1%2526f%3DG%2526l%3D50%2526co1%3DAND%2526d %3DPTXT%2526s1%3DCadex.ASNM.%2526OS%3DAN%2FCadex%2526RS% 3DAN%2FCadex
g) Below, we show he same patent in a more convenient format for printing and reading.
   U.S. Pat. No. 10,302,709, dated 28 May 2019. By Shoa Hassani Lashidani et al.
   http://patft.uspto.gov/netacgi/nph-Parser?Sect1=PTO1&Sect2=HITOFF&d=PALL&p=18u=%2Fnetahtml%2FPTO% 2Fsrchnum.htm&r=1&f=G&l=50&s1=10,302,709.PN.&OS=PN/10,302,709&RS=P N/10,302,709
h) Item more:
   U.S. Pat. No. 9,692,088 Koba et al. 27 Jun. 2017.
   http://patft.uspto.gov/netacgi/nph-Parser?Sect1=PTO1&Sect2=HITOFF&d=PALL&p=1&u=%2Fnetahtml%2FPTO% 2Fsrchnum.htm&r=1&f=G&l=50&s1=9,692,088.PN.&OS=PN/9,692,088&RS=PN/9,692,088
i) Item more:
   U.S. Pat. No. 7,619,417 Kiang 17 Nov. 2009
   http://patft.uspto.gov/netacgi/nph-Parser?Sect2=PTO1&Sect2=HITOFF&p=1&u=/%2Fnetahtml%2FPTO%2Fsearch -bool.html&r=1&f=G&l=50&d=PALL&RefSrch=yes&Query=PN%2F7619417
   This patent, in the section “Capacity”, page 12, lines 55 to 58 says literally;
   “It seems logical that it would be easy to calculate the low rate capacity of a battery, but in actually discerning this property has been and continues to be a challenge to the battery industry”.

In other words, at the time this patent was written it was not known how to find the capacity of a battery. This patent is held by Shoa Hassani, so it seems that no progress has been made to date.

In addition, none of them can predict the behaviour of the battery at any time in its life and especially when the temperature changes.

### EXPLANATION OF THE METHOD

### Glossary

Many of the terms explained here are well known, but they should be made vey specific given the many misconceptions found in many books and publications.

a) B, W, A: Generic name of batteries. B is reserved for those that are new, charged, fully formed and at rest. Those batteries that are subject to this method are called W, with a certain age, even new ones, at any time of their life, and at any temperature. W and B are initially the same battery, it is called B when it is new and W when it is old. A is used for the equivalent batteries which are new and charged, that is to say those type B which will have an ED identical to the remaining energy available to the battery W being analysed.

This patent uses as an example the sealed lead acid battery with glass wool separators. by their acronym SLA-AGM. Sealed lead acid absorbed glass material.

b) BEC: It is the Electrical Balance of Consumption. Note that such balance must be very complete, where not only the discharges are included, but also the charges, as for example those coming from a braking in an EV. And any current that may produce stress to the battery, such as extra opening and closing currents, harmonics, etc., and also the foreseeable temperatures during each charge or consumption.

This balance is usually variable in relation to time. Using the EV as an example, to obtain it you must enter the speed chosen, the driving style, the weight and load of the vehicle, and the use or not of other consumers. If more autonomy is required, the BEC can be changed by introducing lower requirements, in order to increase it. Some of the information can also be fixed, such as the slopes of a road to be travelled, or dynamic, and even alien to our actions, such as a variable temperature during such a journey. It is assumed that the EV has access to forecasts or telematic information. It can be equipped with an alarm if consumption or autonomy changes. It is not the object of this patent to analyse or obtain the BEG that is assumed to be known.

c) Capacity. This is the ability of a battery to transform the maximum possible electrochemical potential into useful electricity under certain circumstances. And, if it is rechargeable, it measures its aptitude for transforming electricity into the maximum possible electrochemical potential. It is measured in Ah.

Although what is really considered is always energy, so it is understood that the voltage is always known. Sometimes it is given as the possible watts to supply during a certain time, with a final voltage V_{f} and at the regulated temperature. In this last case, useful energy is directly promised. The differences in the initial capacity of a battery, and the maximum capacity reached after a few cycles, as a function of the complete formation, etc., are not considered. The capacity decreases when the temperature decreases or when the discharge intensity increases.

ch) Nominal capacity C_{N}. This is the initial capacity of a new battery. It is defined, according to the Standard, as that which allows an I_{N} discharge in a time I_{N}, at a temperature T_{N}, and with a final voltage V_{f}. Being verified: C_{N}=I_{N}×t_{N}

d) Minimum capacity Cₘ, The Standard defines the lowest acceptable remaining capacity according to the use to which the battery is destined. Cₘ usually varies between 0.6 and 0.8 C_{N}.

e) Remaining capacity C_{R} of a battery, is the one existing at a given moment, when part of the expected life has elapsed and a certain initial capacity has been lost.

f) C. This is the capacity of an equivalent battery A that is found as a result of this method. It will be equal to or less than the C_{N} of the battery analysed. It also has a generic meaning.

g) Cn. It is the capacity at temperature Tₙ of a battery W that at T_{N} had a capacity of C_{N}. At a lower temperature than Tₙ, it is lower than C_{N}. There is a curve that relates them. This curve is valid at any time during its life.

h) Remaining charge. Useful electrical energy is also called charge. When a discharge is partial or if the temperature changes, the charge that remains available in the battery is called residual charge or remaining energy, which are an approximation of ED, the difference being the minimum non-operational charge,

i) Available energy, ED. This is the maximum energy that can be obtained from a W battery at any time in its life, discharging it under certain conditions, until the final voltage V_{f} is reached. All batteries, especially rechargeable batteries, have a final discharge voltage, which varies according to the intensity of discharge. In the case of rechargeable batteries, this V_{f} is the minimum that should not be exceeded, since it represents an irreversible deterioration of the battery. On the other hand, it is usually close to the minimum operating voltage of the equipment it supplies.

In primary batteries this concept is not applicable, as the equipment simply stops working. At that point V_{f}, there is a certain minimum charge, or minimum energy, which is proportionally very small. The concept of ED is the total remaining energy minus that minimum energy that should not be available to avoid damaging the battery, and which is usually neglected because of its relatively very small value. It is easy to calculate. This minimum energy varies for the same battery depending on the temperature and the discharge intensity, ID. Given the small difference, and in a first approximation, we will accept in certain points to use indistinctly ED, remaining charge or active electrochemical potential.

j) State of charge. The level or amount of percentage charge remaining in the battery W, as opposed to the maximum capacity at that time, is called the state of charge. The capacity of a battery has no relation to the state of charge, nor to the open circuit voltage when it is charged. It is necessary to know both the capacity and the state of charge at the same time in order to know the ED. There is a curve that relates the state of charge to the voltage. The acronym in English is SOC, state of charge.

k) EV. This is the English acronym for electric vehicle. This is usually the name given to 100% electric vehicles. If they are mixed, they are called hybrids, HEV. And if they are additionally plug-in, PHEV.

I) G_{n,l}. Given a new battery B with capacity Cₙ, voltage V_{N} and temperature Tₙ, G_{n,l}, is the name of a family of discharge curves generated by the same fixed ID, I, applied to B and to several new and charged batteries of different capacities below B, all at the same temperature. The ID is predetermined manually or by the System, and usually varies between 0.1 Cₙ and 2 Cₙ Amp., and the capacity of the batteries to be discharged varies between 0.1 Cₙ and Cₙ Ah. A possible example is G_{n,1′0}, which is the family corresponding to the temperature Tₙ at which battery B has a capacity of Cₙ. A discharge equal to 1.0 Cₙ Amp. is chosen for the following batteries which have, for example, capacities of 0.3 Cₙ, 0.5 Cₙ, 0.7 Cₙ, and Cₙ Ah. These curves allow their interpolation. See FIG. 1.

m) ID, Iᵢ, I_{N}. Intensity of discharge, and also in plural. The first two stands are generic. With the second one, it is possible to refer to a set of generic discharge intensities Iᵢ, which by varying the sub-index, allows to represent several specific intensities. The reference standard is I_{N}. It is measured in amperes and, as a guideline, in this method varies between I_{N} Amp. and 60 I_{N} Amp.

In SLA batteries, the usual discharges vary between 0.01 and 3 C_{N} Amp. The norm for knowing the capacity in lead is usually 0.05 C_{N} Amp. and I_{N}=20 h. Discharges can be down till V_{f} voltage, so that the battery is not damaged. The curves are represented on orthogonal Cartesian coordinate axes that measure the voltage on the ordinates and the time on the abscissa on a logarithmic scale.

It should be noted that when a battery is required to be discharged at I Amp. what is really done is to require energy, that is, watt hours are discharged, since demand is carried out at a certain voltage and during a certain period of time.

n) MCU. Abbreviation of Micro Controler Unit. It comprises the CPU (Central Processing Unit), with one or more multicore microprocessors, memories, algorithms, software, etc.

n̅) Standard. Ascribed to our sector, it is the set of rules, formulations, criteria, specifications and technical standards that limit, specify, typify and define the parameters that characterise batteries. It allows to know and compare easily their performances. Among the best known technical standards are DIN, JIS, IEC, CEI, UL. While some focus on technical considerations, others do so on safety of use.

The Standard can be dictated by anyone, but it is highly recommended to follow the known ones. In our case, specific for each technology the working temperature, time and intensity of discharge, nominal voltage and minimum V_{f} at different intensities of discharge, normal capacity C_{N} and minimum Cₘ, among other things. All the measurements and curves must follow this Standard. Each technology and Standard implies different curves.

o) p. It is the percentage of electrochemical potential or ED of an equivalent battery A with capacity C, that has been consumed when making an incomplete discharge over the total initial potential. Therefore, ED 1−p) is equal to the remaining ED.

p) Electrochemical potential. This is the energy resident in certain chemical substances which, when correctly activated, can provide electrical energy. The battery is a suitable container that contains a series of products with electrochemical potential, and is the physical medium where the reaction that transforms such potential energy into electricity takes place.

There is no electricity in a charged and insulated battery. Electricity will only properly exist when the electrochemical reaction that generates it occurs. And to trigger it, an external circuit connected to the battery is necessary. Electricity is produced by the chemical reaction that such a connection causes.

The potential energy of a charged and a discharged battery are different. The first situation is called active electrochemical potential, and the second passive electrochemical potential.

q) UPS. Acronym for Uninterruptible Power Supply. In Spanish SAI.

r) System. Name of the device that allows to automate the calculation of the method, for which it comprises a set of elements such as MCU, memories, microprocessors, electronic circuits, algorithm processor, voltmeter, discharger, ammeter, temperature sensor, chronometer, capacity to calculate parameters and generate curves, also including adapter, the corresponding software and hardware, interface, etc., that allows us to inform about the variables and receive the results, and even to consider information via telematics, It is also occasionally called a Battery Management System (BMS), Although the latter term is often used for a much simpler management of control over the charge, discharge, and limiter.

s) SLA-AGM. Acronym for Sealed Lead Acid and Absorbed Glass Material, which means into sealed lead acid with fiberglass separators. It is the battery technology that this patent uses as example, since is possibly the most popular, mature, and with a fairly stable evolution,

t) SOC. Acronym for State of Charge. Very frequently used it the sector.

u) t_{N}. Nominal time. This is the time that the Standard sets to elapse when battery B is discharged at current I_{N}, at T_{N} temperature and without the voltage dropping below V_{f}. When referring to generic time values, t is used. If t_{M} is written, it means that it is the maximum time of autonomy of a battery with capacity C, at a specific ID. Logarithmic graphs are usually applied where the abscissa is the ID and the ordinate is the autonomy. See FIG. 4. t_{N}=20h usually is used for lead.

v) T_{N}. It is the temperature that the Standard proposes to measure the normalized values, and particularly during the basic generation of curves. When the temperature varies, the subscript “n” in Tₙ is used generically. Usually Tₙ is between −30° C., and 60° C. There is a curve that relates it to the capacity. If one Ah is required of a battery at different temperatures, the energy cost will be different.

w) Nominal voltage V_{N}. It is defined by the electrochemical technology of the battery construction. This voltage or tension results from the algebraic sum of the normal reduction and oxidation potentials at 25° C. of the electrodes. Thus, and as an example, it is calculated below for a lead battery. In the discharge with a 4 molal concentration of sulphuric acid, the normalised oxidation potential of the positive electrode PbO₂, cathode, at 25° C., is of the order of +1.70 Volts. And for the negative electrode Pb, anode, the reduction potential is about −0.33 Volts. Add 2.03 Volts. The negative must be subtracted. And this is its V_{N}. It can rise or fall with the concentration of acid, hence the measurement of the density of the electrolyte in open batteries gives an idea of its state of charge, since the discharge decomposes part of the acid into water. The charge of the battery implies a reverse circulation of electricity, and the electrodes will reverse their polarity. If a secondary battery at rest has a voltage lower than V_{N}, it needs an urgent recharge.

x) Maximum voltage V_{M} is what the battery reaches when it is t rest and fully charged. It must always be higher than V_{N}.

y) Intermediate voltage Vᵥ. This is a generic voltage that varies between V_{M} and V_{f}.

z) Final voltage V_{f}. This is the minimum that can be reached in a discharge to avoid damage to the battery. At that end point V_{f} there will still be a certain very small remaining charge. The end-voltage V_{f} varies according to the intensity of the discharge. See more under i).

### Theoretical Basis

This method has its academic origin in an approach that has not evolved so far. A large part of the industry implicitly poses the problem as if the battery were a petrol tank. It is required at any time and under any condition that the same litres that has been introduced, are available. In the case of the battery, the same ampere-hours supplied. And it is not like that.

The patented method is valid for both primary and rechargeable batteries, open or sealed, and of any technology, as long as that we discount the memory effect. For secondary batteries, reversibility does not only consist of the electrochemical process, but also of the mechanical process, since the active masses must be replaced on the corresponding electrodes when the charging process regenerates them. These reactions are always exothermic, so some of the energy used will be used for heat production.

As the G_{n,l} curves are the basis of this patent, their obtaining is explained below. Given a new battery B with a capacity Cₙ, voltage V_{N}, and at a temperature Tₙ, this is the name given to a family of discharge curves produced by the same fixed ID I, applied to B and to several new batteries of different capacities lower than B, always at the same temperature. The ID is predetermined manually or by the System, and usually varies between 0.1 Cₙ and 2 Cₙ Amp. and capacities between 0.1 Cₙ and Cₙ Ah.

A possible example is G_{n,1′0}, which is the family corresponding to the temperature Tₙ, at which battery B has a capacity of Cₙ. A discharge equal to 1.0 Cₙ Amp. is chosen for the following batteries, which have capacities of 0.3 Cₙ, 0.5 Cₙ, 0.7 Cₙ, and Cₙ Ah. These curves allow their interpolation. See FIG. 1.

The same discharge I is then used and applied to W, which returns a Vᵥ response, starting a new discharge curve. With this response we look for an equivalent battery A in G_{n,l}, which allows us to find ED. The behavior of A will be identical to that of the battery W at that moment, so to consider any change of ID or Tₙ, we will use this equivalent battery, which will have the same response. In our example, the generated curve is the one of points, and A will have a capacity of 0.4 Ah. See FIG. 1. If Tₙ change, changes also all the curves.

Re-evaluating the criteria for choosing IDs, it should be considered that the curves produced provide a clear and differentiable response. If the discharge were proportionally very small, the proximity of the response curves to each other would make it difficult to differentiate them. Neither should the discharge be too large as this would imply over-dimensioned connections and resistances for the targets.

When an ID is proportionally very high, the capacity decreases greatly because the electrochemical reaction does not have time to complete reaching the entire active mass, as well as the energy dedicated to producing heat. The heat that must be dissipated, supposes an irrecoverable loss of electrochemical potential, although the effect is small since the time is very short, between five and twenty seconds. In addition, a certain amount of stress is placed on the battery.

Pulses of any type can also be used. The situation of the battery should be considered as far as is known to be consistent with the ID. It is always advisable to start with the minimum operational discharges. In general they vary between 0.1 Cₙ and 2 Cₙ Amp. In the case of SLA-AGM it is possible to start between 0.6 Cₙ and 1 Cₙ.

This method is applicable to any W battery at any time in its life. If, from previous measurements, the current capacity is known, even if it is out of date, this value should be taken as the starting point instead of the nominal capacity when it was new. However, it is still assumed that no prior information is available.

Likewise, and as utilities or applications there are the following. Once the ED and the BEC are known, the autonomy can be calculated at the desired temperature. Even in the case that the temperatures and discharges that occur are variable.

Capacity can also be calculated. After a recharge, when we notice that the charger does not supply appreciable electricity to the battery, we disconnect it and calculate

ED. This value is the capacity of the battery W at the measurement temperature. If the battery is primary, the ED coincides with its capacity at all times.

With the curve of the evolution of the capacity in time, the remaining life t_{N} can be calculated. It should be clarified that the correct use of the term expected life t_{W}, serves to specify the maximum time of life of a new product under certain circumstances. The same concept can be used for batteries. It is more interesting to find the remaining life t_{R} in our patent, that is the remaining useful life from any moment on. It is convenient to start from the knowledge of the L_{M} and L_{D} curves, which are provided by the manufacturer and can be standardised.

To calculate these curves, orthogonal Cartesian axes are used, in which time is measured in the abscissa and capacities in the ordinate. L_{M} is calculated by using the battery as carefully as possible, and by memorising the points formed, over its lifetime, by its capacity value and the time of its measurement. L_{M} ends at the point that indicates its maximum life (f_{M}, Cₘ) where the ordinate reaches the minimum operating capacity Cₘ. See FIG. 5.

In the same way there is the Lo curve, where the battery is treated abusively, producing a great premature deterioration, whose life extends to (t_{D}, Cₘ). Both curves start from the same point (0, C_{N}/Cₙ), as the batteries evaluated are identical. If the usual capacity measurement temperature is Tₙ, this point is (0,Cₙ).

Finally, the W battery, which is analysed, has generated an L_{W} curve up to a point P (t_{P}, C_{R}), at which point it is interesting to know the remaining life t_{R}. The t_{P} coordinate is the time elapsed from its entry into service until the remaining life t_{R} is required.

It is accepted, for the time being, that the treatment that the battery will receive is similar to that received. From point P it is easy to interpolate between L_{M} and L_{D} to extrapolate the curve to Cₘ, and obtain on the one hand the real expected life t_{w}, with the particular treatment received, and thus we obtain the remaining life t_{R} from point P which is: t_{R}=t_{W}−t_{P}.

If a change in treatment or living conditions is expected, interpolation allows this to be considered. In FIG. 5 it has been assumed that such expected treatment was similar to that already received. If this were not the case, the mathematics would draw a curve closer to L_{M} or L_{D}.

### Information and Equipment Needed for Analysis

It is necessary to have at least the equipment and data listed below.
a) The manufacturer provides information on the technology used in the manufacture of the W battery, its nominal capacity C_{N} and its nominal voltage V_{N} when new, curves, etc., and the Standard applied to define the battery, (DIN, JIS, SAE, etc.).
b) A temperature sensor is required to measure the temperature of the W battery at the time of analysis. This data allows us to know the capacity Cₙ at that temperature Tₙ, when it was new, through of the corresponding curve.
c) There must be a discharger, with appropriate connections to the battery, which allows the choice of IDs that will be in the order of 0.1, 0.6, 1.0, 1.2, 1.4, and 2 Cₙ Amp. or intermediate. A preferential ID of 1.0 Cₙ Amp is proposed. But any other can be used. Additionally it's necessary an ammeter and a voltmeter.
d) The family of discharge curves G_{n,l}, corresponding to the temperature Tₙ.
e) Logarithmic tables at the different temperatures of the range, which inform about the autonomy according to the discharge for each capacity, measuring the discharges in the abscissa and the autonomy in the ordinate, differentiating according to technologies and voltage. The final voltage V_{f} of the battery must always be respected, following the Standard. An example is included in FIG. 4.
f) To calculate the autonomy, it is necessary to know the BEC.

g) In the event that a charger is detected to be acting, it must be possible to disconnect it. Nor are variable charges or discharges allowed at any time during the analysis at a manual or laboratory level. Although in the Industrial Application if they can be considered as well as to carry out iterations that allow a greater precision.
h) In order to calculate the expected life, t_{w} and the remaining t_{R} at a given moment, it is necessary to have information on how the battery is going to be treated, and it is also convenient to have the L_{M} and L_{D} curves.

### Explanation of How the Method Works

It is explained here how to obtain ED in a simple way, with the help of basic apparatus.

The simplified flow diagram is followed according to FIG. 2. Later, in the Preferential Realization, the way to automate all this is explained, so that it can be used simply by any user.

When the analysis is started, two situations can occur. That the battery is in perfect rest, or that it is supporting a discharge. The ammeter clarifies in which case we are in. It begins with a W battery in rest according with the following order;
1) The battery technology is known, and its C_{N} capacity when new, its nominal voltage V_{N}, as well as the G_{n,l1} curves for the chosen ID, I₁.
2) The sensor supplies the temperature of W which turns out to be Tₙ. The use of the corresponding curve allows us to know the capacity of the battery W, when B was new, at such a temperature, which turns out to be Cₙ.
3) The battery became connected, and the discharger sets the initial ID that results to be I₁, following the user's criteria and the recommendations given in the Theoretical Base, If there are reasons to believe that, given the conditions of the battery, it may have a capacity lower than Cₙ, the ID is suitably reduced. This intensity must be the same as that used to generate G_{n,l}.
4) The download begins. The discharge curve is observed for the necessary time, a few seconds, until it stabilizes and a stable voltage Vᵥ is obtained, and therefore the beginning of the discharge curve. If this curve is not clear, we will continue trying with some more time or with other discharges. Each discharge implies different G_{n,l} curves.
5) As an example we propose G_{n,1′0}, where we look, interpolating if necessary, for the curve produced by the discharge Iₜ=1′0 Cₙ Amp. to battery W, and which response with the voltage Vᵥ. In this example it is the curve corresponding to 0.4 Cₙ Ah. See FIG. 1. This discharge curve is equal to that produced by an equivalent battery A, new, charged, and with a capacity of C=0.4 Cₙ Ah.
6) It is concluded that the ED of the battery analysed W, has a behaviour analogous to that of an equivalent battery A, new, with a capacity C=0.4 Cₙ Ah, and fully charged. Now we know the required ED, which turns out to be that of battery A.

In the second case, there is consumption that is unwanted or unavoidable, which turns out to be a common situation. An EV is again given as an example. Some consumers cannot be inhibited, such as the clock, the on-board computer, etc., even though we can turn off for the calculation the most important ones, such as the engine, or the air conditioning. In this case, you must obtain instantaneous and perfectly simultaneous values for the ammeter, I₂, and the voltmeter, V₂. Then proceed as follows.
1) I₂, V₂ and battery temperature Tₙ are available.
2) Also of the curves G_{n,l2} corresponding to I₂ amperes and to the temperature T. The discharge I₂ generates a curve that starts with V₂ which gives an equivalent battery A₂ with a C₂ capacity that when new and charged shall give same response.
3) If I₂ is too small, then the additional discharge of I₁ Amp. is added. Which is the same as if the battery were at rest, and the previous process is repeated taking into account that now the search is made for G_{n,l3} since the ID is now:

I₃=I₂+I₁ Amp.

If this method has been used previously, when the battery was no longer new, and its current capacity is known approximately, the latter is used as the starting point. Therefore, strictly speaking, only in the first calculation is C_{N} used. In subsequent calculations, the last capacity found is used as the starting point. Therefore, the original capacity is never repeated in successive uses of the method. Except when it is used iteratively to refine the answer.

Once the ED has been calculated at the measurement temperature, as a utility or application, and known the BEC, the autonomy can be found. An example is given below.

Let it be a W battery, with its known ED, corresponding to an equivalent capacity of C₁. The BEC informs that two consecutive discharges D₁ and D₂ will be carried out separately. The first D₁, at current I₁ and at temperature T₁, has a duration of t₁. It is understood that this discharge does not exhaust the battery. Then, with the remaining energy, the second D₂ discharge is carried out, consisting of an ID of I₂, at a temperature T₂, and for the maximum time that this remaining energy allows. We are interested to calculate said autonomy.

The combination of the proposed downloads makes it possible to address all possible approaches to consumption. The percentage p of energy of W that D₁ consumes over the total available is then calculated.
a) With the logarithmic table FIG. 4 corresponding to our parameters T₁, I₁, C₁, etc., you can find the total autonomy time t_{M1} allowed by the battery.
b) The ratio t₁/t_{M1}, is the approximate percentage of energy used by D₁ during t₁. In other words, p. The remaining energy is C₁ (1−p), which corresponds to a new battery equivalent to C₂, which is then used.
c) Again with the logarithmic table and the curves corresponding to D₁, I₂, C₂ and T₂, there is t_{M2}. This point informs about the total time of autonomy of W with the previous conditions.

Using time introduces a certain error since we do not know the average values of V, which are more laborious to find in the last section of the curve. A quicker calculation can be made assuming the average values of V. Although if we carry out a sensitivity analysis it is verified that errors of 2 or 3% in its calculation, produce small variations in the value of energy. Finally, it would be more correct to obtain the equation of the discharge curve and make an integration, but it would add unnecessary accuracy and evident complexity. When the method is automated in the Preferred Embodiment, the calculation of the ED is instantaneous and exact.

Finally, two additional utilities or applications are presented here. When the battery being analysed is fully charged and at rest, the ED provides the capacity. And with the curve of its evolution in time, its expected life t_{w} and the remaining t_{R}, provided that the subsequent treatment that the battery will receive is known.

### BRIEF DESCRIPTION OF THE DRAWINGS

Five figures are included to help understand the method. They are particularizations, so they can be replaced by others even with variations, without losing validity or affecting the scope of what has been exposed.

In FIG. 1, it is showing an example of a family of discharge curves G_{n,1′0} Cₙ, of a new battery B with a capacity Cₙ, at temperature Tₙ, and using an ID, I=1′0 Cₙ Amp. The smaller batteries we choose have capacities of 0.3 Cₙ Ah, 0.5 Cₙ Ah and 0.7 Cₙ Ah. If the same discharge I is now applied to the battery W, the voltage response Vᵥ, begins to generate a curve which turns out to be 0.4 Cₙ Ah. which is the one corresponding to the equivalent battery A.

In FIG. 2, a simplified diagram is showing the flow of actions to find ED is represented, known as the data that define the W battery. This diagram is not complete for the sake of clarity. For example, the steps applied to V₁ asking about stability, cycle counter etc., have been saved in V₂ and V₃. Knowing C₁, C₂ or C₃ means knowing A₁, A₂ or A₃, and therefore ED.

FIG. 3 represents a simplified diagram that follows the automated process of the method being patented applied to a device, that is the Preferred Embodiment.

FIG. 4 shows an example of logarithmic tables at 25° C. and voltage V that provide information on autonomy, depending on the ID and capacity of the SLA-AGM batteries. In this case we choose 0.3 Cₙ Ah, 0.5 Cₙ n Ah, 0.7 Cₙ Ah and CₙAh.

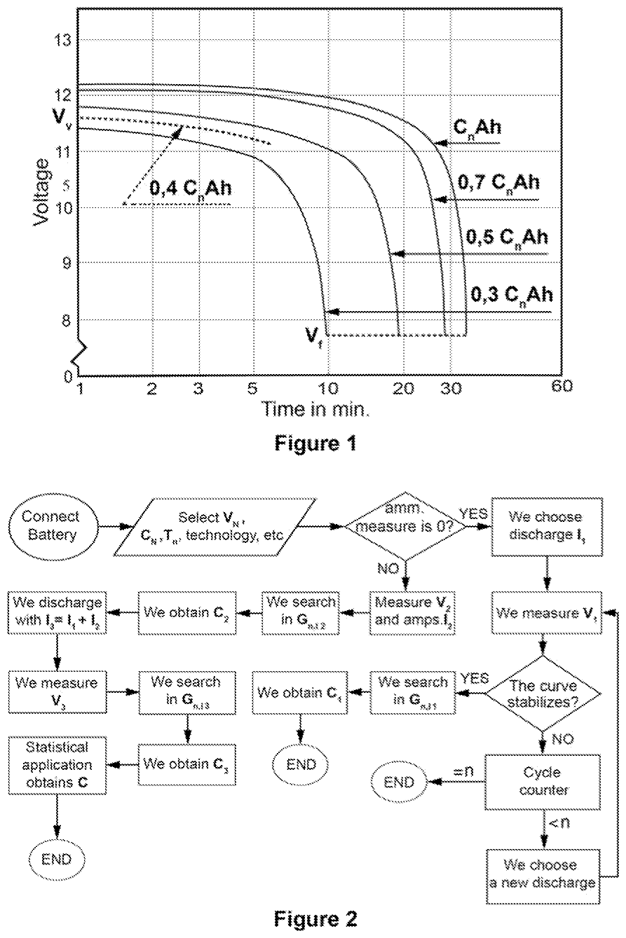

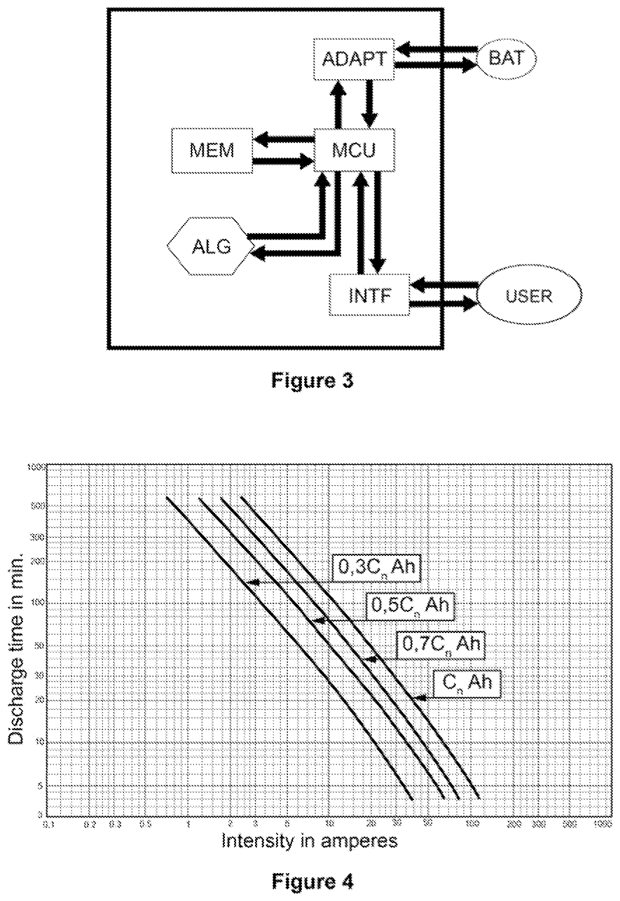

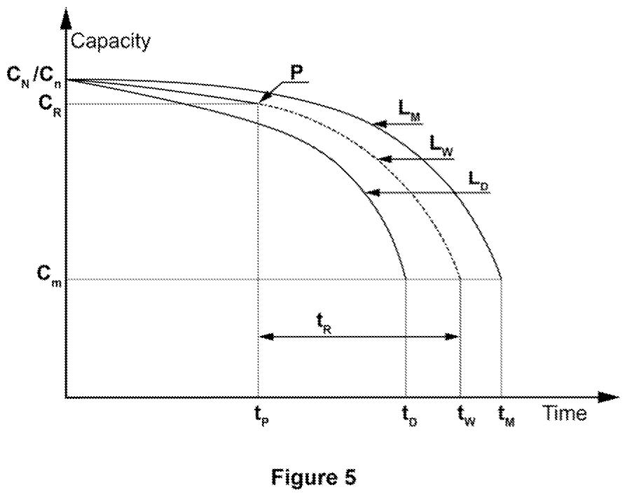

In FIG. 5 the curves L_{M}, L_{D}, and L_{W} are drawn, that allow to find the expected life t_{w} and the remaining life t_{R} of W.

### Preferred Embodiment

The purpose is to manufacture a device that automates the above method of finding the ED of a W battery, It can be portable or not, and with capacity adjustment on the characteristics of the different batteries to be analysed in certain voltage or capacity ranges. Or it can be adapted from the beginning to a particular battery.

A System is required that comprises an interface, an adapter, a discharger, a temperature sensor, a voltmeter, an ammeter, a chronometer, an MCU and the necessary software to record, store and analyse the curves produced by the discharger and compare them with those in memory by means of the algorithms provided, etc This software will control the device, as well as communications with external equipment. It is enabled for the technology and Standard specified by the battery manufacturer and is greatly simplified if prepared for a specific battery. In this way its use includes the following steps:
A) The manufacturer first reports on the battery technology as well as its C_{N} capacity, nominal voltage V_{N}, curves, etc., when B was new.
B) All data are entered into the System via the interface. Once the W battery is connected, the analysis begins. There are batteries which, when connected, transmit all their characteristics to the System. However, this is not necessary when the application is made to a concrete battery, as is the case with an EV or a mobile phone.
C) The ammeter checks whether the battery is in standby. Initially, it is considered to be inactive.
D) The sensor supplies the temperature at which the battery is, Tₙ. With this temperature and the corresponding curve resident in the memory that relates the capacities and temperatures, the System determines the capacity Cₙ, which is the one corresponding to B, and which is the best approximation we have in the first analysis.
E) The System, following the instructions it has memorised, chooses the initial discharge intensity I₁. This discharge can feed a super capacitor and use the energy accumulated later.
F) Once the System obtains a stable response voltage V₁, it searches in G_{n,l1}, interpolating if necessary, the curve that starts with the voltage you have just measured. This curve is the same that produce the discharge of a new equivalent battery A₁, charged, and with a capacity of C₁.
G) With the known ED, the System can choose to display it in an interface, or supply it to another equipment that needs it, which is easily integrated into the device we already have.

Now suppose that the System ammeter detects that there is a continuous, and stable discharge. If the discharge does not have such conditions, instantaneous and simultaneous values must be measured. The ammeter provides to the System with the current consumption I₂, the voltmeter the voltage V₂, the sensor the W battery temperature Tₙ, and Cₙ is calculated. The steps outlined are then followed.
1) Search in G_{n,l2}, obtained with I₂ amperes and at temperature Iₙ, the discharge curve corresponding to V₂. As before, it obtains the one corresponding to an equivalent battery A₂, with a new and charged C₂ capacity.
2) The System now adds an additional discharge I₁, calculated as before for the case where the battery was at rest, and repeats the previous process, taking into account that you must look for G_{n,l3}, as the discharge intensity is I₃=I₁+I₂. It obtains C₃. If you notice that I₂ is equal to or greater than I₁, you will reduce the first one by substracting what is appropriate. Even cancelling it, and taking for granted C₂.

In theory C₃ should be similar to C₂. However, since the battery is not at rest, nor balanced, the measurements may be altered. Probably the capacity found in last place C₂ is more accurate, but it is reasonable to calculate a weighting giving the weight to each one according to what the concrete application advises. Additional consecutive iterative measurements can also be made by changing the discharge etc. After this calculation, the ED is known, at the measurement temperature, that is the equivalent battery A₃.

As a utility or application, known the BEG, autonomy can be found easily and quickly, in the same way already explained. This speed allows that once the BEG has been applied, if the resulting autonomy is inadequate because it is insufficient, additional searches for new autonomies can be carried out. For which we could modify the BEC, eliminating or lowering the demands that can be reduced. Or accepting those that the device proposes.

Using an EV as an example, the cruise speed can be reduced. Or the device can propose a new one, or a combination of several depending on the profile of the road, and the temperatures expected on the different sections that will allow the required range. It is easy to incorporate it into autonomous driving.

Another application is to find the capacity of the battery. If, at he end of a charge, the System detects that the charger does not supply any current or is very small, it disconnects the charger and proceeds to calculate ED. In these conditions the ED found coincides with the capacity of the battery.

In the case of a UPS bench, it allows to know quickly the ED. As it is a device that is usually perfectly charged, disconnecting the charger and the charges for a few seconds (and even without disconnecting them if it is not possible), the ED is the same as the remaining capacity. A certain amount of rest would be desirable. but the distortion is always the same, and can be considered.

In another application, the System saves in the memory the capacities found over a period of time, generates a curve and extrapolates it, considering its database where L_{M} and L_{D} are, and knowing the predictable treatment, allows to obtain the expected life t_{w} and the remaining t_{R}. In FIG. 5 we have considered that the treatment will be similar to the one previously received.

In addition to the advantages already mentioned, the rapid response of this device allows a more efficient use of battery power, as well as a more correct maintenance, and even to locate prematurely any anomaly. Or equalizing the cells of a pack in production. All this means optimising the performance and life of the battery with the corresponding cost savings.

In this case, the Preferred Embodiment coincides with the Industrial Application.

1-10). (canceled)

11. A method to calculate the energy available, ED, in an electric battery W at any moment in its life without discharging it, as well as its autonomy, capacity and remaining life, the following information and equipment at least is needed for this purpose,
a) Knowledge of all the parameters and curves that define the used battery W when it was new B, as well as several new batteries of lower capacity, at the working temperature Tₙ, in order to calculate the G_{n,l} curves,
b) A discharger, voltmeter, ammeter, temperature sensor, and a charger that can be disconnected, with suitable connections,
wherein, the method comprises the following steps of the obtaining of the G_{n,I} discharge curves, given a new battery B with capacity Cₙ, voltage V_{N} and temperature Tₙ, this is the name of a family of curves produced by the same ID fixed I, applied to B and to several new batteries of different lower capacities, all at the same temperature,
in order to apply the method, the necessary connections are made, and there are two possible situations that the ammeter will detect:
I) That the battery is at rest, isolated, without charge or discharge,
II) That there is a discharge that cannot or is not desired to be avoided,
First case, a discharge I₁ is carried out at W producing a response voltage V₁, going to the family of curves G_{n,I1}, we find the capacity C₁, corresponding to an equivalent battery A, the ED of A is identical to the ED of W,
Second case, if the existing ID is I₂ and the voltage V₂ is searched in G_{n,I2}, C₂ is obtained, then, an additional discharge I₁, already calculated, is superimposed, leaving I₃=I₁+I₂, which produces a response voltage V₃, and with it the capacity C₃ is searched in G_{n,I3}, which, weighted with C₂, provides the ED.

12. Method according to claim 11, wherein the step of obtaining the discharge curves G_{nI} as follows, given a new battery B with a capacity Cₙ voltage V_{N} and temperature Tₙ, we produce by the same ID fixed I, the discharge applied to B and to several new and charged batteries of different capacities below B, all at the same temperature.

13. Method according to claim 11, wherein the step of obtaining autonomy, including knowledge of ED and the use of the BEC, static or dynamic.

14. Method according to claim 11, wherein the step of obtaining the capacity of the battery W, for this purpose, a device comprising an ammeter and a charger is used. In the moment that is detected that the current provided to W when recharging is very small or null, the charger is disconnected and, at that moment, the ED calculated turns out to be the capacity.

15. Method according to claim 14, wherein the step of finding the remaining life t_{R} of a battery W, at a given moment P(t_{P}, C_{R}), which comprise knowing the expected treatment and interpolation between the L_{M} and L_{D} curves, until the ordinate reaches the operating capacity Cₘ, thus obtaining the expected life t_{w}, the operating time at the moment of calculation t_{P} is subtracted from this value, which gives the remaining life t_{R}.

16. A system that automates the method of claim 11, to calculate the available energy ED of any electric battery W, at any moment of its life, without discharging it, as well as its autonomy, capacity and remaining life, wherein the system comprising interfaces, a discharger, thermal sensor, voltmeter, ammeter, chronometer, an MCU with the necessary software to record, memorize, and analyze the curves produced by the discharger and compare them with those in the memory provided by the manufacturer or previously calculated, as well as all the precise data, algorithms, and control communications with external equipment, or the like,
the system checks whether the W battery is in standby or not. If it is, it checks the temperature Tₙ, chooses the discharge, finds the equivalent battery A in G_{n,I} and its ED, if the battery is not at rest, it will first find, always with the help of the G_{n,I} curves, the ED corresponding to the discharge detected, another discharge intensity is superimposed, and with the sum of both, the ED is recalculated, with weighting between the two.

17. System according to claim 16, wherein finding the remaining autonomy, which comprise knowing ED and the BEC, the BEC can be dynamic and the temperature can change, which implies new values of ED, considering also the incorporation of data through the interface as well as through any telematic way.

18. System according to claim 16, wherein obtaining the capacity of W, the system comprises a charger and an ammeter, at the end of the W recharge, when the ammeter detects that the current it receives is null or very small, the System software proceeds to disconnect the charger and find ED, a value that coincides with the capacity of W at that moment and at that temperature.

19. System according to claim 18, wherein obtaining the remaining life t_{R} of a W battery at any time t_{P}, for which the System generates the L_{w} curve with the capacities as a function of time up to t_{P}. Knowing the expected treatment of W, the System interpolates L_{W} between L_{M} and L_{D} and extrapolates to y=Cₘ, obtaining the expected life t_{w}, from which t_{P} is subtracted to obtain t_{R}.

20. System according to claim 6, comprising a software that memorises and uses all the data provided by the manufacturer, comprising the specifications of the different batteries, discharge curves at different temperatures, the one that relates capacity and temperature, controlling all the hardware included in the System, which comprise reading, registering and using the databases provided, communicating with the interfaces, and with any equipment outside the System, including the dynamic data that informs it by any telematic means, or the like.
